(19) United States
(12) Patent Application Publication
(10) Pub. No.: US 2010/0190401 A1
(43) Pub. Date: Jul. 29, 2010

(54) Transparent Planar Material for Architectural Purposes

(75) Inventors: Gerhard Mangold, Wutoschingen (DE); Wolfgang Siefert, Ettenheim (DE)

Correspondence Address: GUDRUN E. HUCKETT DRAUDT, SCHUBERTSTR. 15A, WUPPERTAL, 42289, DE

(73) Assignee: ROWO COATING GESELLSCHAFT FUER BESCHICHTUNG MBH, Herbolzheim (DE)

(21) Appl. No.: 12/664,109

(22) PCT Filed: Jun. 5, 2008
(86) PCT No.: PCT/DE2008/000931

§ 371 Date: Jan. 25, 2010

(30) Foreign Application Priority Data
Jun. 11, 2007 (DE) 10 2007 027 271.7

(51) Int. Cl. B32B 15/08; C23C 14/34; B32B 27/12

(52) U.S. Cl. 442/131; 428/421; 428/447; 428/500; 204/192.15

(57) ABSTRACT

The invention relates to transparent planar material (1) for architectural purposes, having several coatings (2, 2′, 3). Said coating system is selective on wavelength having a high transmission in the visible spectral range and high reflection in the infrared spectral range. The mentioned coatings are metal coatings (3) and metal-oxide coatings (2, 2′).

The invention concerns the use of a flat material wherein the flat material comprises a flexible plastic film that is light-transparent or a flexible coated fabric that is light-transparent and wherein the flat material has several wavelength-selective coatings for an increased transmission of the visible spectral range as well as for an increased reflection of the infrared spectrum range; the invention further concerns a method for producing such a flat material.

The “architectural purposes” in the most general sense are to be understood such that the flat material according to the invention in some way or another can be used in architectural constructions, i.e., in optically transparent roof and façade constructions. Application examples are, for example, tent membranes as well as awning and sun shade fabrics.

The “flat material” is to be understood also in the most general sense, i.e., as substantially a flat member. In the following, it may also be referred to as membrane or substrate.

Transparent flat materials for architectural purposes can be, for example, formed of extruded films of fluoropolymers. They are highly transparent and have better light transmission values than, for example, glass. In a disadvantageous way the materials and manufacturing processes do no allow for product variants with which in a targeted fashion the wavelength spectrum of the sunlight can be influenced. For example, an effective reflection of sunlight in the non-visible infrared range is possible only with simultaneous total blockage of light transmission in the visible wavelength range. Moreover, the applied layers (in particular aluminum) are strongly corrosive and must therefore be protected by a coat of lacquer. The latter, in turn, negatively affects the reflection properties. Finally, print patterns on the flat material only result in a shading action.

In addition to the aforementioned extruded films, there are also coated fabrics, in particular fiberglass fabrics coated with Teflon, polyester fabrics coated with PVC or fiberglass fabrics coated with silicone. They are suitable for self-supporting spanning of large areas and enabled complex shaping as a result of their flexibility. However, these coated fabrics also have disadvantages. For example, light passage is only minimal. The maximum translucence is around 18 to 20%. Moreover, the materials are not transparent but only translucent with an opaque light transmission. These materials and manufacturing processes also do not allow for product variants with which it is possible to influence the wavelength spectrum of the sunlight. Thus, an effective reflection of sunlight in the non-visible infrared range is also possible only with simultaneous total blockage of light transmission in the visible wavelength range. Furthermore, the applied layers are strongly corrosive and must therefore also be protected by a coat of lacquer. This again negatively affects the reflection properties. Moreover, the coated fabrics are very expensive. Finally, the period of utilization of such coated fabrics in comparison to extruded films of fluoropolymers is limited.

The invention has the object to provide a special use of the flat material of the aforementioned kind for architectural purposes; furthermore, a method for producing such a flat material is to be provided.

As a technical solution the invention proposes the use of the flat material according to the features of claim 1.

The basic idea of the transparent flat material according to the invention for architectural purposes resides in a selective radiation transmission with high transparency of the visible light. In this connection, the membrane is provided with a wavelength selective coating that has on the one hand a high transmission in the visible spectrum range and, at the same time, as a result of a high reflection, a minimal transmission in the near and far infrared spectrum range. The metal coating reflects in this connection the infrared spectral range while the additional coating in the visible spectral range effects an antireflective action for increasing light transmission. This means that the transmission of the visible spectral range in any case is greater than the transmission of the—near and far—infrared spectral range. Of course, the transmission of the visible spectral range is not absolutely 100% but less. The portion of infrared spectral range which is not reflected is almost completely absorbed by the flat material. In this way, the coating acts in the sense of an antireflection coating with respect to the visible spectral range so that in this way the light transmission is significantly increased. In this connection, extinguishing interference effects of the waves happen during antireflection action. The high reflection in near and far infrared spectral range of the metal coating ensures that the penetration of solar energy and the loss of heating energy is reduced to a minimum. The flat material can be comprised of one or several layers of film or film fabric composites or coated fabrics or combinations thereof. In this connection, on one or several surfaces of the membrane layers a wavelength-selective coating is applied. In a concrete embodiment, the flat material is a plastic film or a coated fabric in particular of the materials fluoropolymer, silicone or PVC. The fabric as such is comprised preferably of glass. These materials, because of their minimal surface energy and the resulting bad adhesion of all materials and the UV resistance, are very well suited for architectural purposes.

This transparent flat material according to the invention for architectural purposes has a plurality of advantages. For example, the flat material with respect to structural-physical respects provides a high heat insulation to the exterior as well as to the interior. This means a minimal heat loss at night or during the heating period. For incident solar radiation this means a reduced air conditioning expenditure. Furthermore, the flat material according to the invention is characterized by a high light transmission which reduces otherwise common, required illumination devices. Since the flat material as a result of its transparency is embodied to be transparent a clear large surface area view of the exterior is provided. Moreover, an adaptation to geographic, climatic or solar conditions is possible. For example, by variations of the coating structure of the selective layer by constructive variations of the material layer structure, the properties can be matched to geographic and climatic conditions. Also, in this connection tailoring of the material can be varied. With regard to energy, the inventive flat material enables a reduction of energy consumption, namely with respect to air-conditioning as well as heating. This results in a reduction of CO₂ loading by reduced energy consumption. Finally, the flat material according to the invention also has architectural advantages with regard to utilization as flexible films and fabric membranes. This is so because the design possibilities of the membrane structure are significantly better utilizable in comparison to prior art flat materials. The light and light passage can be employed as design elements.

An embodiment according to claim 2 proposes that the additional coating is embodied as a metal oxide coating. With appropriate metal oxides, a higher degree of antireflection in the visible spectral range can be achieved.

A further embodiment proposes according to claim 3 a multi-layer, in particular 3-layer or 5-layer, wavelength-selective coating system (additional coating—metal coating etc.). In this way, the selectivity of the radiation passage can be increased. A 5-layer system in place of a 3-layer system can increase even more the selectivity of the radiation passage. For example, a typical structure of a coating with selective radiation passage is comprised of several layers of metal oxide-metal-metal oxide or metal oxide-metal-metal oxide-metal-metal oxide. Such layer systems can be applied by means of sputtering technology in roll-to-roll processing on flexible substrates.

The embodiments according to claims 4 and 5 propose special metals or metal oxides of the corresponding coatings. The series of materials is not limiting in this connection. Other materials are conceivable.

Basically, it is conceivable and advantageous when the wavelength-selective coating is installed for protection purposes at the inner side and thus is not exposed to the weather. Systems in which the wavelength-selective coating is applied externally, according to the embodiment of claim 6 have preferably an additional protective layer.

As a technical solution for the method for producing a transparent flat material according to the invention for architectural purposes, the characterizing portion of claim 7 proposes sputtering technology.

The advantage resides in that the described layer systems by means of sputtering technology can be applied without problem onto flexible substrates and can be deposited with satisfactory adhesion on the aforementioned substrates. In this way, in one pass several different layers can be applied.

One embodiment of the transparent flat material according to the invention for architectural purposes will be explained in the following with the aid of the drawings. It is shown in:

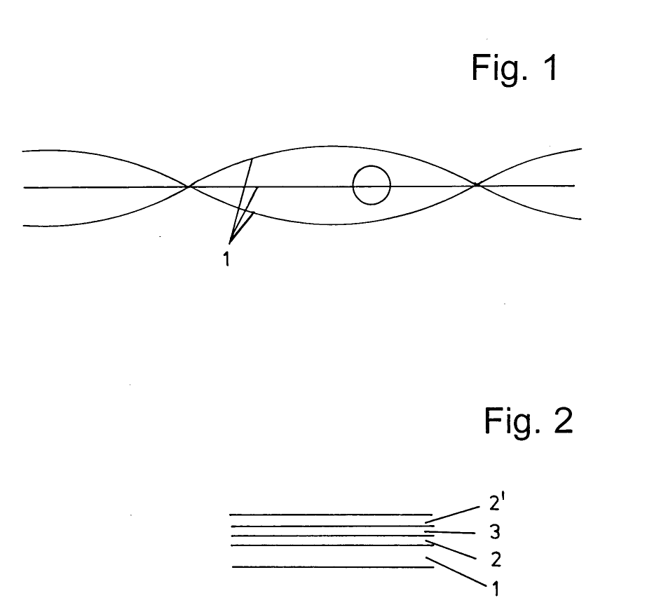

FIG. 1 a schematic section view of a system of a cushion of three material layers;

FIG. 2 a detail view of the illustration of FIG. 1.

The flat material 1 in the form of an extruded film of plastic material or a coated fabric, in particular of glass, has in this embodiment a 3-layer coating. The first layer directly applied onto the flat material 1 is a metal oxide layer 2. On it there is a metal coating 3. On the latter there is in turn a metal oxide layer 2′.

Basically, it is conceivable that further metal or metal oxide coatings may be provided, in particular a 5-layer coating in total.

The function of this layer system is as follows:

The coating system is wavelength selective with a high transmission in the visible spectral range and with a high reflection (and thus minimal transmission) in the near and far infrared spectral range. In this connection, the infrared radiation is reflected at the metal coatings 3 while the two metal oxide coatings 2, 2′ effect by interferences an antireflection effect in the visible spectral range.

In a 5-layer system these effects are even more intensified in comparison to the afore described 3-layer system.

FIG. 1 shows an architectural application of such a system in the form of a cushion of three material layers. In this connection, between the individual material layers intermediate air spaces are provided.

In the illustrated embodiment only the central layer is provided with a coating system like the one illustrated in FIG. 2. It is however also conceivable to provide two of the three layers or all three layers each with a coating system.

Of course, it is conceivable that only one material layer, two materials layers or more than three material layers are provided. This cushion principle—as mentioned before—represents a typical configuration of the system in the architectural field.

In one embodiment, a layer system of metal oxide-metal-metal oxide may be applied onto an ETFE film with a transmission of 67% and an emission capability of 5% as a membrane material in a cushion construction for optically transparent roof and façade constructions.

Another embodiment may provide a layer system of metal oxide-metal-metal oxide on an ETFE film with a transmission of 80% and an emission capability of 15% as a membrane material in a cushion construction, also for optically transparent roof and façade constructions.

### LIST OF REFERENCE NUMERALS

1 flat material
2 metal oxide coating
2′ metal oxide coating
3 metal coating

What is claimed is:

1.-7. (canceled)

8. A flat material for architectural purposes comprising:
a plastic film that is flexible and light-transparent or a fabric that is flexible and light-transparent and that has a fabric coating, wherein the plastic film or the coating is comprised of a fluoropolymer, silicone or PVC;
a wavelength-selective coating applied onto the plastic film of the fabric for an increased transmission of a visible spectral range and for an increased reflection of an infrared spectral range;
wherein the wavelength-selective coating is comprised of three layers or five layers;
wherein the three layers are a first layer of metal oxide, a second layer of metal, and a third layer of metal oxide;
wherein the five layers are a first layer of metal oxide, a second layer of metal, a third layer of metal oxide, a fourth layer of metal, and a fifth layer of metal oxide;
wherein the layers of metal oxide provide anti-reflective action in the visible spectral range by extinguishing interference effects of the waves;
wherein the layer/s of metal reflect/s the infrared spectral range; and
wherein the unreflected portion of the infrared spectral range is absorbed by the flat material.

9. The flat material according to claim 8, wherein the metal of the layer of metal is selected from the group consisting of Ag, Au, Cu, Al, Cr, and NiCr.

10. The flat material according to claim 8, wherein the metal oxide of the layer of metal oxide is selected from the group consisting of SiO₂, TiO₂, SnO₂, In₂O₃, Be₂O₃, and Nb₂O₅.

11. The flat material according to claim 8, comprising a protective layer on an outermost one of the three layers or five layers as a protection against weather effects.

12. The flat material according to claim 8, wherein the fluoropolymer is ETFE.

13. The flat material according to claim 8 in the form of a membrane for roof and façade construction.

14. A method for producing a transparent flat material according to claim 8, comprising the step of sputtering a wavelength-selective coating onto the flat material.
